(19) United States
(12) Patent Application Publication
(10) Pub. No.: US 2015/0096720 A1
(43) Pub. Date: Apr. 9, 2015

(54) HEAT DISSIPATION MODULE

(71) Applicants: INVENTEC CORPORATION, Taipei (TW); Inventec (Pudong) Technology Corporation, Shanghai (CN)

(72) Inventors: Mao-Ching LIN, Taipei (TW); Kuo-Chin HUANG, Taipei (TW)

(73) Assignees: INVENTEC CORPORATION, Taipei (TW); Inventec (Pudong) Technology Corporation, Shanghai (CN)

(21) Appl. No.: 14/163,607

(22) Filed: Jan. 24, 2014

(30) Foreign Application Priority Data
Oct. 8, 2013 (CN) 201310464418.3

(51) Int. Cl. H05K 7/20

(52) U.S. Cl. CPC H05K 7/20336; H05K 7/2039
USPC 165/104.21

(57) ABSTRACT

A heat dissipation module includes a heat conducting plate having an upper surface, a stacked fins heat sink in thermal contact with and disposed on the upper surface of the heat conducting plate, at least one heat pipe and multiple fins. The evaporation end is in thermal contact with and disposed on the upper surface. The plurality of fins are located on the upper surface and positioned at intervals. Each of the fins has at least one through hole and the condensation end runs through the at least one through hole.

### CROSS-REFERENCE TO RELATED APPLICATIONS

This non-provisional application claims priority under 35 U.S.C. §119(a) on Patent Application No(s). 201310464418.3 filed in China, P.R.C. on Oct. 8, 2013, the entire contents of which are hereby incorporated by reference.

### BACKGROUND OF THE INVENTION

1. Technical Field of the Invention

This disclosure relates to a heat dissipation module, more particularly to a heat dissipation module with a stacked fin heat sink and a heat pipe running through another multiple fins.

2. Description of the Related Art

As the processing capability of an electronic component increases, the processing efficiency thereof improves. The heat generated by the electronic component, however, grows accordingly, which cause the electronic component to fail because of high temperature. To solve this problem, a heat dissipation module is usually installed for heat dissipation.

Generally speaking, in today's heat dissipation module, a heat conducting plate is in thermal contact with a heat source and then a heat pipe is used for transfering heat to multiple fins in order to dissipate the heat. In this heat dissipation module, the heat pipe penetrates the multiple fins so it is hard to reduce the size of the heat dissipation module. On the other hand, the heat pipe is vital for heat transfer so the heat dissipation module cannot work effectively without the heat pipe. Hence, it is very important to design a heat dissipation module having the heat pipe not only capable of being installed in limited space, but also with excellent heat dissipation efficiency.

### SUMMARY OF THE INVENTION

A heat dissipation module comprises a heat conducting plate having an upper surface, a stacked fins heat sink in thermal contact with and disposed on the upper surface of the heat conducting plate, at least one heat pipe and a plurality of fins. The evaporation end is in thermal contact with and disposed on the upper surface. The plurality of fins are located on the upper surface and positioned at intervals. Each of the fins has at least one through hole and the condensation end runs through the at least one through hole.

### BRIEF DESCRIPTION OF THE DRAWINGS

The disclosure will become more fully understood from the detailed description given herein below and the drawing are for illustration only, and thus does not limit the present disclosure, wherein:

FIG. 1 is a perspective view of a heat dissipation module according to one embodiment of the disclosure;

FIG. 2 is a front view of a heat dissipation module according to one embodiment of the disclosure;

FIG. 3 is a perspective view of a heat dissipation module according to another embodiment of the disclosure; and

FIG. 4 is a front view of a heat dissipation module according to another embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

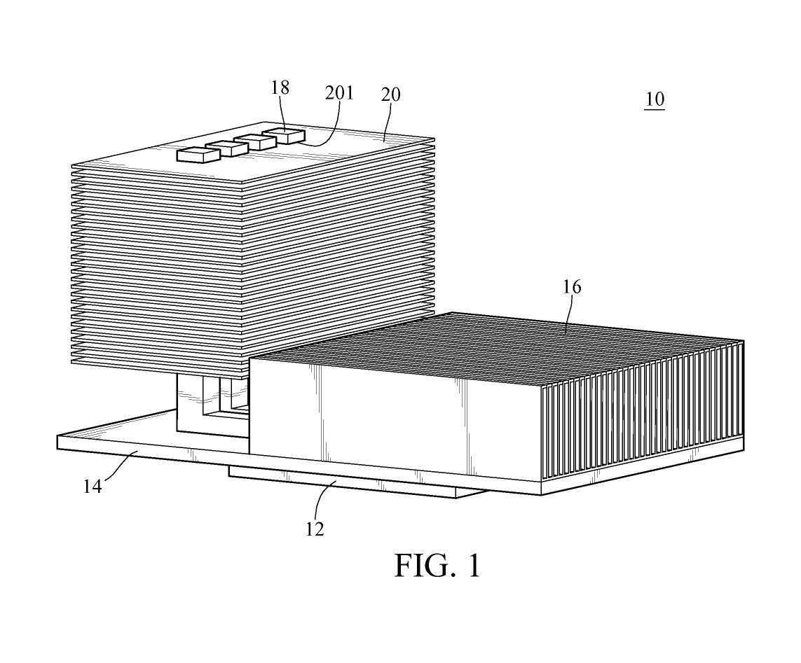

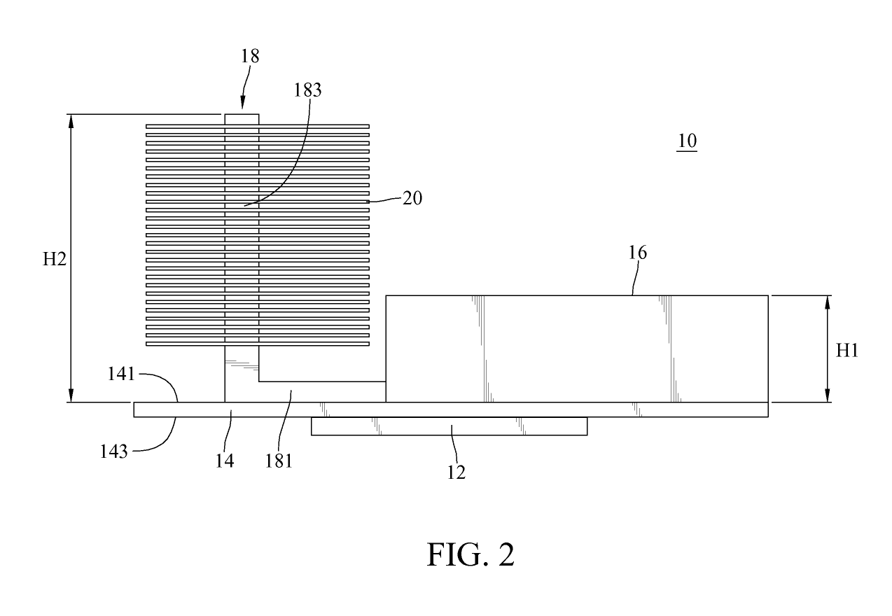

FIG. 1 is a perspective view of a heat dissipation module according to one embodiment of the disclosure. FIG. 2 is a front view of a heat dissipation module according to one embodiment of the disclosure. As seen in FIG. 1 and FIG. 2, the heat dissipation module 10 of this embodiment comprises a heat conducting plate 14, a stacked fin heat sink 16, four heat pipes 18 and a plurality of fins 20.

The heat conducting plate 14 has an upper surface 141 and a lower surface 143. In this embodiment, the lower surface 143 is in thermal contact with a heat source 12, but it is not intended to limit the disclosure. For example, in another embodiment, the lower surface of the heat dissipating plate is not in thermal contact with the heat source 12. In contrast, the evaporation end of the heat pipe is in thermal contact with the heat source 12 directly. This will be illustrated in detail later, in the description of another embodiment of the disclosure. In this embodiment, the heat conducting plate 14 is a vapor chamber. The working process of the vapor chamber is similar to that of the heat pipe. That is, the fluid circulates in an enclosed flat chamber while evaporating and condensing, so that the temperature can distribute evenly. However, the heat transfer method of the heat pipe is one dimensional (because the heat transfers along the heat pipe), while that of the vapor chamber is two dimensional (because the chamber is planer shaped). As a result, the vapor chamber can not only transfer the heat to the desired place like heat pipe, but also can distribute heat rapidly. Nonetheless, the conducting plate 14 is not limited to the vapor chamber. In other embodiments, the conducting plate 14 may be a plate made by aluminum or copper.

The stacked fin heat sink 16 is disposed on the upper surface 141 of the heat conducting plate 14. Specifically, the stacked fin heat sink 16 is multiple fins stacked together and each of the stacked fin heat sink 16 is perpendicular to the heat conducting plate 14. Moreover, a first distance H1 is formed between the top of the stacked fin heat sink 16 and the heat conducting plate 14. The stacked fin heat sink 16 is in thermal contact with the heat conducting plate 14, so the heat conducting plate 14 can transfer the heat to the stacked fin heat sink 16. Thereby, the heat can be dissipated from the stacked fin heat sink 16. In this embodiment, the material of the stacked fin heat sink 16 is copper, but the disclosure is not limited thereto.

The four heat pipes 18 each has an evaporating end 181 and a condensation end 183. The evaporating end 181 is disposed on the upper surface 141 of the heat conducting plate 14, and the evaporating end 181 is in thermal contact with the upper surface 141 of the heat conducting plate 14 (as shown in FIG. 2). Additionally, a second distance H2 is formed between the top of the condensation end 183 of each heat pipe 18 and the heat conducting plate 14, while the first distance H1 is less than the second distance H2 (as shown in FIG. 2). In this embodiment, the number of the heat pipes 18 is four, but it is not limited thereto. In other embodiments, the number of the heat pipes 18 may be one, two three or more than four. The plurality of fins 20 are located above the upper surface 141 of the heat conducting plate 14, and theses fins 20 are positioned at intervals. That is, adjacent two fins of these fins 20 are separated apart by a distance and are stacked together. Each fin 20 has four through holes 201 corresponding to the four heat pipes 18. In this embodiment, the number of through holes 201 is four, but it is not limited thereto. In other embodiment, it can be adjusted in order to fit the number of the heat pipes, so the number thereof can be one, two three or more than four. The condensation end 183 of each heat pipe 18 penetrates the corresponding through holes 201. Since the evaporation end 181 of each heat pipe 18 is in thermal contact with the upper surface 141 of the heat conducting plate 14 and the condensation end 183 of each heat pipe 18 runs through the through hole 201, the heat from the heat source 12 can be transferred to the evaporation end 181 of each heat pipe 18. Then, the heat is transferred to the condensation end 183 of each heat pipe 18. Lastly, the heat is dissipated by the fins 20 penetrated by the four heat pipes 18.

As seen in FIG. 1 and FIG. 2, the heat dissipation module 10 comprises both the stacked fin heat sink 16 and multiple fins 20 penetrated by the heat pipes 18. In this heat dissipation module 10, the first distance H1 between the top of the stacked fin heat sink 16 and the heat conducting plate 14 is less than the second distance H2 between the top of the condensation end 183 of each heat pipe 18. Therefore, for those electronic devices with limited spaces therein, the heat dissipation module 10 is able to occupy less internal space because of the use of the stacked fin heat sink 16. Furthermore, the heat dissipation module 10 of this embodiment still has heat pipes 18 penetrating the fins 20, so the heat can be transferred effectively via the heat pipes 18. Consequently, the heat dissipation module 10 of this embodiment can be mounted in limited space without sacrificing its heat dissipation efficiency.

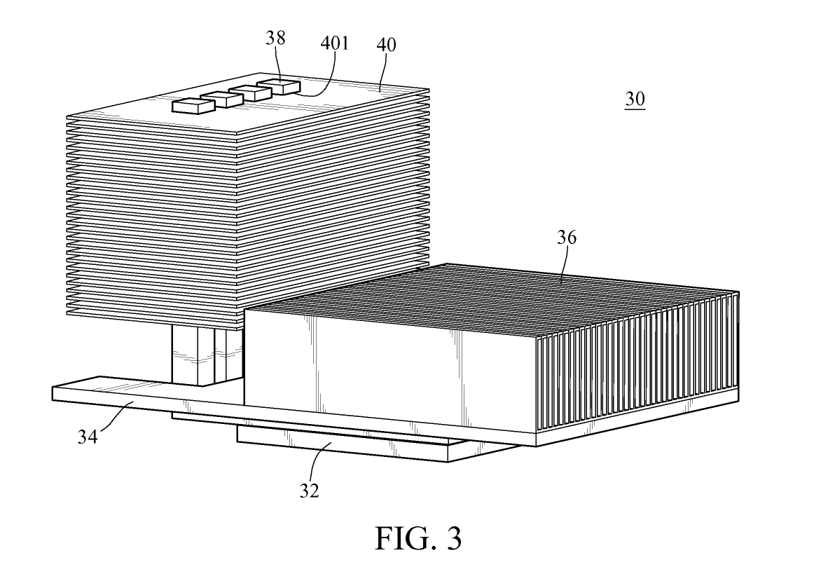

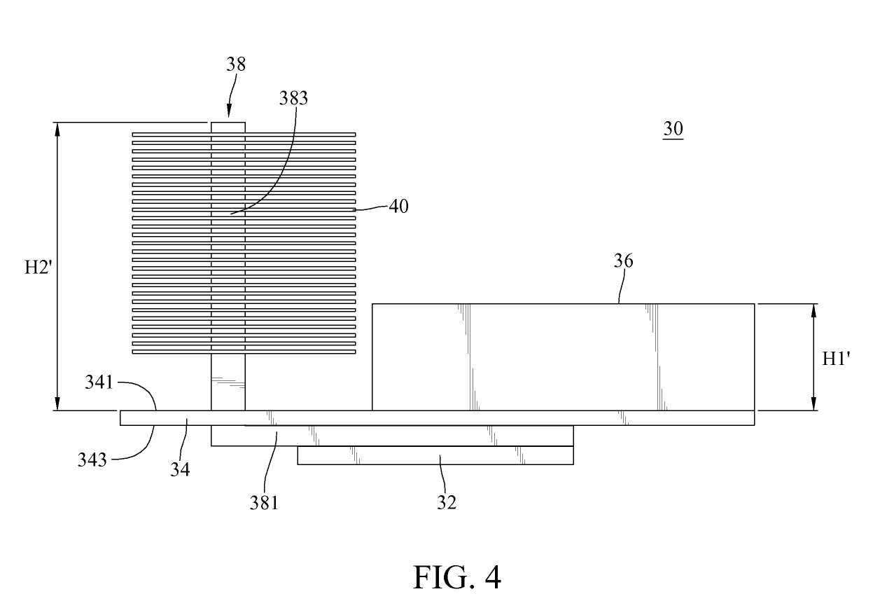

FIG. 3 is a perspective view of a heat dissipation module according to another embodiment of the disclosure. FIG. 4 is a front view of a heat dissipation module according to another embodiment of the disclosure. As seen in FIG. 3 and FIG. 4, the heat dissipation module 30 of this embodiment comprises a heat conducting plate 34, a stacked fin heat sink 36, four heat pipes 38 and a plurality of fins 40.

The heat conducting plate 34 has an upper surface 341 and a lower surface 343. In this embodiment, the heat conducting plate 34 is a vapor chamber. The working process of the vapor chamber is already illustrated in the above-mentioned description so it will not be repeated again. Also, the heat conducting plate 34 is not limited to be the vapor chamber. In other embodiments, it can also be a plate made by aluminum or copper.

The stacked fin heat sink 36 is disposed on the upper surface 341 of the heat conducting plate 34. Specifically, the stacked fin heat sink 36 is multiple fins stacked together and since they are disposed, each of the stacked fin heat sink 36 is perpendicular to the heat conducting plate 34. Moreover, a first distance H1′ is formed between the top of the stacked fin heat sink 36 and the heat conducting plate 34. The stacked fin heat sink 36 is in thermal contact with the heat conducting plate 34, so the heat conducting plate 34 can transfer the heat to the stacked fin heat sink 36. Thereby, the heat can be dissipated from the stacked fin heat sink 36. In this embodiment, the material of the stacked fin heat sink 36 is copper, but the disclosure is not limited thereto.

The four heat pipes 38 each has an evaporating end 381 and a condensation end 383. The condensation end 383 is disposed on the upper surface 341 of the heat conducting plate 34, and the evaporating end 381 is in thermal contact with the lower surface 343 of the heat conducting plate 34 and two opposite sides of the evaporating end 381 are in thermal contact with the lower surface 343 and the heat source 32, respectively (as shown in FIG. 4). Additionally, a second distance H2′ is formed between the top of the condensation end 383 of each heat pipe 38 and the heat conducting plate 34, while the first distance H1′ is less than the second distance H2′ (as shown in FIG. 4). In this embodiment, the number of the heat pipes 38 is four, but it is not limited thereto. In other embodiments, the number of the heat pipes 38 may be one, two three or more than four. The plurality of fins 40 are located above the upper surface 341 of the heat conducting plate 34, and theses fins 40 are positioned at intervals. That is, adjacent two fins of these fins 40 are separated apart by a distance and are stacked together. Each fin 40 has four through holes 401 corresponding to the four heat pipes 38. In this embodiment, the number of through holes 401 is four, but it is not limited thereto. In other embodiment, it can be adjusted in order to fit the number of the heat pipes, so the number thereof can be one, two three or more than four. The condensation end 383 of each heat pipe 38 penetrates the corresponding through holes 401. Since the evaporation end 381 of each heat pipe 38 is in thermal contact with the upper surface 341 of the heat conducting plate 34 and the condensation end 383 of each heat pipe 38 runs through the through holes 401, the heat from the heat source 32 can be transferred to the evaporation end 381 of each heat pipe 38. Then, the heat is transferred to the condensation end 383 of each heat pipe 38. Lastly, the heat is dissipated by the fins 40 penetrated by the four heat pipes 38.

As seen in FIG. 3 and FIG. 4, the heat dissipation module 30 comprises both the stacked fin heat sink 36 and multiple fins 40 penetrated by the heat pipes 38. In this heat dissipation module 30, the first distance H1′ between the top of the stacked fin heat sink 36 and the heat conducting plate 34 is less than the second distance H2′ between the top of the condensation end 383 of each heat pipe 38. Therefore, for those electronic devices with limited spaces therein, the heat dissipation module 30 is able to occupy less internal space because of the use of the stacked fin heat sink 36. Furthermore, the heat dissipation module 30 of this embodiment still has heat pipes 38 penetrating the fins 40, so the heat can be transferred effectively via the heat pipes 38. Consequently, the heat dissipation module 30 of this embodiment can be stored in a limited space without sacrificing its heat dissipation efficiency.

The above-mentioned heat dissipation module comprises both the stacked fin heat sink and the heat pipe running through the multiple fins (different from the stacked fin heat sink). The use of the stacked fin heat sink reduces the partial size of the heat dissipation module, so that it can be installed inside the electronic device with limited inner space. Moreover, this heat dissipation module still has heat pipe penetrating the fins, so the heat can be effectively transferred during the heat dissipation process. As a result, the heat dissipation module of the disclosure can be installed in limited space without sacrificing its heat dissipation efficiency.

Additionally, in the heat dissipation module, the vapor chamber is used for better thermal diffusion, thereby achieving excellent heat dissipation efficiency.

What is claimed is:

1. A heat dissipation module comprising:
a heat conducting plate having an upper surface and a lower surface;
a stacked fins heat sink in thermal contact with and disposed on the upper surface of the heat conducting plate;
at least one heat pipe having an evaporation end and a condensation end, wherein the evaporation end is in thermal contact with the upper surface; and
a plurality of fins located on the upper surface and positioned at intervals, wherein each of the fins has at least one through hole and the condensation end runs through the at least one through hole.

2. The heat dissipation module according to claim 1, wherein the heat conducting plate is a vapor chamber.

3. The heat dissipation module according to claim 1, wherein the material of the heat conducting plate is aluminum or copper.

4. The heat dissipation module according to claim 1, wherein a first distance is formed between the top of the stacked fin heat sink and the heat conducting plate, a second distance is formed between the top of the condensation end and the heat conducting plate, and the first distance is less than the second distance.

5. The heat dissipation module according to claim 1, wherein the lower surface is in thermal contact with a heat source.

6. The heat dissipation module according to claim 1, wherein the evaporation end of the at least one heat pipe is disposed on the upper surface of the heat conduction plate.

7. The heat dissipation module according to claim 1, wherein the evaporation end of the at least one heat pipe is disposed on the lower surface of the heat conduction plate.

8. A heat dissipation module comprising:
a heat conducting plate having an upper surface and a lower surface;
a first fin module comprising a plurality of fins contacting with the heat conducting plate;
at least one heat pipe having an evaporation end and a condensation end; and
a second fin module comprising another plurality of fins contacting with the at least one heat pipe, wherein the condensation end protrudes through each of the fins of the second fin module.

9. The heat dissipation module according to claim 8, wherein the heat conducting plate is a vapor chamber.

10. The heat dissipation module according to claim 8, wherein the material of the heat conducting plate is aluminum or copper.

11. The heat dissipation module according to claim 8, wherein a first distance is formed between the top of the first fin module and the heat conducting plate, a second distance is formed between the top of the condensation end and the heat conducting plate, and the first distance is less than the second distance.

12. The heat dissipation module according to claim 8, wherein the lower surface is in thermal contact with a heat source.

13. The heat dissipation module according to claim 8, wherein the evaporation end of the at least one heat pipe is disposed on the upper surface of the heat conduction plate.

14. The heat dissipation module according to claim 8, wherein the evaporation end of the at least one heat pipe is disposed on the lower surface of the heat conduction plate.
